(19) United States
(12) Patent Application Publication
(10) Pub. No.: US 2025/0275242 A1
(43) Pub. Date: Aug. 28, 2025

(54) ARRAY SUBSTRATE AND DISPLAY PANEL

(71) Applicant: Yungu (Gu’an) Technology Co., Ltd., Langfang (CN)

(72) Inventors: Bo XIA, Langfang (CN); Guobing HE, Langfang (CN); Sheng GUO, Langfang (CN); Miaomiao TIAN, Langfang (CN); Pei DUAN, Langfang (CN); Zhili MA, Langfang (CN)

(73) Assignee: Yungu (Gu’an) Technology Co., Ltd., Langfang (CN)

(21) Appl. No.: 19/209,690

(22) Filed: May 15, 2025

(30) Foreign Application Priority Data
Jun. 7, 2024 (CN) 202410741845.X

(51) Int. Cl. H10D 86/40

(52) U.S. Cl. CPC H10D 86/441

(57) ABSTRACT

The present disclosure discloses an array substrate and a display panel. The array substrate includes a first power signal transmission structure and a second power signal transmission structure. In a second area, the first power signal transmission structure includes a first structure and a second structure that are insulated from each other, the first structure and the second structure being arranged in a first direction; and the second power signal transmission structure includes a third structure, a part of the third structure located in the second area being disposed between the first structure and the second structure, and the third structure extending in a second direction to an active area, where the second direction intersects the first direction.

### CROSS-REFERENCE TO RELATED APPLICATIONS

The present application claims priority to Chinese Patent Application No. 202410741845.X, filed on Jun. 7, 2024 and entitled “ARRAY SUBSTRATE AND DISPLAY PANEL”, which is incorporated herein by reference in its entirety.

### FIELD

Embodiments of the present disclosure relate to the field of display, and in particular to an array substrate and a display panel.

### BACKGROUND

With the continuous development of display panels, users have an increasing demand for narrow bezels. A power signal line is disposed inside a bezel. As the bezel of the display panel is narrower and narrower, the width of the power signal line is narrower and the resistance of the power signal line is thus larger, which is likely to cause overheating of the display panel.

### SUMMARY

The present disclosure provides an array substrate and a display panel to alleviate the overheating phenomenon of the display panel.

In a first aspect, the embodiments of the present disclosure provide an array substrate, including an active area, a first area, a bendable area, and a second area that are arranged in a second direction, and further including a first power signal transmission structure and a second power signal transmission structure,
where in the second area, the first power signal transmission structure includes a first structure and a second structure that are insulated from each other, the first structure and the second structure being arranged in a first direction; and
the second power signal transmission structure includes a third structure, a part of the third structure located in the second area being disposed between the first structure and the second structure, and the third structure extending in the second direction to the active area, where the second direction intersects the first direction.

In one embodiment, the second power signal transmission structure further includes a fourth structure and a fifth structure, the fourth structure being disposed on a side of the first structure away from the third structure, and the fifth structure being disposed on a side of the second structure away from the third structure, where the third structure, the fourth structure and the fifth structure are connected in the first area.

In one embodiment, the third structure includes a first part and a second part, the first part of the third structure being disposed in the first area, and the second part of the third structure being disposed in the bendable area and the second area; the first part includes a first main portion and at least one first branch portion, the first main portion extending in the first direction and being connected to the fourth structure and the fifth structure, and the first branch portion extending in the second direction to the active area;
preferably, the array substrate further includes a third area, the third area and the active area being arranged in the first direction; the first area includes a rounded corner area and a bezel area, the rounded corner area being disposed between the third area and the bezel area; in the bezel area, at least one of: the fourth structure and the fifth structure includes a second main portion and at least one second branch portion; the second main portion extends in the first direction and is connected to the first main portion; the second branch portion extends in the second direction to the active area;
preferably, the number of first branch portions and the number of second branch portions are equal to the number of sub-pixels in one row within the active area;
preferably, the third structure, the fourth structure, and the fifth structure are connected in parallel;
preferably, the active area includes a signal transmission layer configured to provide a drive signal to at least one pixel of the active area; and at least part of the first part of the third structure is disposed in the same layer as the signal transmission layer.

In one embodiment, the signal transmission layer includes a first signal transmission layer and a second signal transmission layer, the second signal transmission layer being disposed on a side of the first signal transmission layer close to a light exit surface; the first main portion of the third structure includes a first conductive layer, the first conductive layer being disposed in the same layer as the first signal transmission layer or the second signal transmission layer;
preferably, the first branch portion of the third structure is disposed in the same layer as the first main portion;
preferably, the first conductive layer of the first main portion includes a first lower layer, a first middle layer and a first upper layer that are disposed in a stack, the first lower layer, the first middle layer and the first upper layer being conductive layers;
preferably, the first lower layer and the first upper layer are made of titanium; and
preferably, the first middle layer is made of aluminum.

In one embodiment, the signal transmission layer further includes a third signal transmission layer disposed on a side of the second signal transmission layer close to the light exit surface; the first main portion further includes a second conductive layer, the first conductive layer being connected to the second conductive layer, and the second conductive layer being disposed in the same layer as the third signal transmission layer;
preferably, the first conductive layer and the second conductive layer are connected in parallel;
preferably, the first branch portion is disposed in the same layer as the third signal transmission layer;
preferably, the second conductive layer includes a second lower layer, a second middle layer, and a second upper layer that are disposed in a stack, the second lower layer, the second middle layer and the second upper layer being conductive layers;
preferably, the second lower layer and the second upper layer are made of titanium; and
preferably, the second middle layer is made of aluminum.

In one embodiment, the active area includes an anode layer disposed on a side of the second signal transmission layer close to the light exit surface and configured to form at least one anode of the pixel in the active area; the first main portion further includes a second conductive layer, the first conductive layer being connected to the second conductive layer, and the second conductive layer being disposed in the same layer as the anode layer;
preferably, the first conductive layer and the second conductive layer are connected in parallel; and
preferably, the first branch portion is disposed in the same layer as the anode layer.

In one embodiment, the array substrate further includes a third area, the third area and the active area being arranged in the first direction; the first area includes a rounded corner area and a bezel area, the rounded corner area being disposed between the third area and the bezel area; in the bezel area, at least one of: the fourth structure and the fifth structure includes a third conductive layer and a fourth conductive layer that are connected in parallel, the third conductive layer being disposed in the same layer as the first signal transmission layer, and the fourth conductive layer being disposed in the same layer as the second signal transmission layer; and
preferably, at least one of: the fourth structure and the fifth structure further includes a fifth conductive layer connected in parallel with the third conductive layer and the fourth conductive layer, the fifth conductive layer being disposed in the same layer as a third signal transmission layer or an anode layer.

In one embodiment, when the first conductive layer of the third structure is disposed in the same layer as the first signal transmission layer, the second signal transmission layer further includes a bridging portion via which the first conductive layer of the third structure and the second conductive layer of the third structure are connected to each other.

In one embodiment, the second part of the third structure includes a first sub-part and a second sub-part, where the first sub-part of the third structure is disposed in the bendable area, and the second sub-part of the third structure is disposed in the second area; the first sub-part is disposed in the same layer as part of the signal transmission layer, and the second sub-part is disposed in the same layer as the signal transmission layer;
preferably, the signal transmission layer includes a first signal transmission layer and a second signal transmission layer, the first sub-part being disposed in the same layer as the first signal transmission layer or the second signal transmission layer; and
preferably, the second sub-part includes a sixth conductive layer and a seventh conductive layer that are connected in parallel, the sixth conductive layer being disposed in the same layer as the first signal transmission layer, and the seventh conductive layer being disposed in the same layer as the second signal transmission layer.

In one embodiment, the first sub-part of the second part of the third structure is disposed in a different layer from the first part of the third structure.

In one embodiment, at least one conductive layer of the fourth structure is disposed in the same layer as the first part; and
preferably, at least one conductive layer of the fifth structure is disposed in the same layer as the first part.

In one embodiment, in the first direction, the first structure and the second structure are symmetrically disposed about the third structure; and
preferably, in the first direction, the fourth structure and the fifth structure are symmetrically disposed about the third structure.

In one embodiment, the first power signal transmission structure further includes a sixth structure, where the sixth structure is disposed in the first area and the bendable area and extends to the active area; and the sixth structure is connected to the first structure and the second structure.

In one embodiment, the sixth structure of the first power signal transmission structure includes a third part, a fourth part, and a fifth part, where the third part is disposed in the bendable area, the fourth part is disposed in the first area, and the fifth part is disposed in the active area; the third part is disposed in the same layer as at least part of the fourth part, and the fourth part is disposed in the same layer as at least part of the fifth part;
preferably, the third part is disposed in the same layer as at least part of a second part of the third structure; and the fourth part and the fifth part are disposed in a different layer from at least part of a first part of the third structure.

In one embodiment, the fourth part of the sixth structure of the first power signal transmission structure includes a third sub-part, a fourth sub-part, and a fifth sub-part, where the third sub-part is disposed between the third structure of the second power signal transmission structure and the fourth structure of the second power signal transmission structure, the fourth sub-part is disposed between the third structure and the fifth structure of the second power signal transmission structure, the fifth sub-part is disposed on a side of the third sub-part and the fourth sub-part close to the active area, and the fifth sub-part extends in the first direction and is connected to the third sub-part and the fourth sub-part.

In one embodiment, the third part of the sixth structure of the first power signal transmission structure is disposed in the same layer as the third sub-part and the fourth sub-part of the fourth part of the sixth structure;
preferably, the active area includes a first signal transmission layer and a second signal transmission layer, the second signal transmission layer being disposed on a side of the first signal transmission layer close to a light exit surface, and the third sub-part and the fourth sub-part being disposed in the same layer as the first signal transmission layer or the second signal transmission layer; and
preferably, the fifth sub-part includes one eighth conductive layer disposed in the same layer as the first signal transmission layer or the second signal transmission layer;
preferably, the fifth sub-part includes two eighth conductive layers connected in parallel, one of the eighth conductive layers being disposed in the same layer as the first signal transmission layer, and the other of the eighth conductive layers being disposed in the same layer as the second signal transmission layer.

In one embodiment, the fifth part of the sixth structure of the first power signal transmission structure is disposed in the same layer as the first signal transmission layer or the second signal transmission layer.

In one embodiment, the third sub-part of the fourth part of the sixth structure of the first power signal transmission structure includes a third main portion and at least one third branch portion, where the third main portion extends in the first direction and is connected to the third part, and the third branch portion is disposed on a side of the third main portion close to the active area and connected to the fifth sub-part; and
preferably, the fourth sub-part of the fourth part of the sixth structure of the first power signal transmission structure includes a fourth main portion and at least one fourth branch portion, where the fourth main portion extends in the first direction and is connected to the third part, and the fourth branch portion is disposed on a side of the fourth main portion close to the active area and connected to the fifth sub-part.

In one embodiment, the third sub-part of the fourth part of the sixth structure of the first power signal transmission structure includes a plurality of third branch portions, the plurality of third branch portions being disposed at intervals; and
preferably, the fourth sub-part of the fourth part of the sixth structure of the first power signal transmission structure includes a plurality of fourth branch portions, the plurality of the fourth branch portions being disposed at intervals.

In a second aspect, the embodiments of the present disclosure further provide a display panel, including the array substrate described in the first aspect.

According to the embodiments of the present disclosure, the second power signal transmission structure is configured to include a third structure, where a part of the third structure located in the second area is disposed between the first structure and the second structure, and the third structure may extend to the active area. As a result, when a second power signal is transmitted through the third structure to the active area, the transmission of the second power signal through a rounded corner area can be prevented, and a line width of the second power signal transmission structure is prevented from being limited by the rounded corner area, thereby alleviating the overheating phenomenon in the rounded corner area.

### BRIEF DESCRIPTION OF THE DRAWINGS

FIG. 1 is a partial structural schematic view of an array substrate provided in the related art;

FIG. 2 is a structural schematic view of an array substrate according to an embodiment of the present disclosure;

FIG. 3 is a structural schematic view of another array substrate according to an embodiment of the present disclosure;

FIG. 4 is a structural schematic view of another array substrate according to an embodiment of the present disclosure;

FIG. 5 is a partial schematic view of the array substrate provided in FIG. 4;

FIG. 6 is a structural schematic cross-sectional view taken along line P1-P1′ in FIG. 5;

FIG. 7 is a structural schematic view of another array substrate according to an embodiment of the present disclosure;

FIG. 8 is a partial schematic view of the array substrate provided in FIG. 7;

FIG. 9 is a structural schematic cross-sectional view taken along line P1-P1′in FIG. 8;

FIG. 10 is a structural schematic cross-sectional view of another array substrate according to an embodiment of the present disclosure;

FIG. 11 is another partial schematic view of the array substrate provided in FIG. 4;

FIG. 12 is a structural schematic cross-sectional view taken along line P2-P2′ in FIG. 11;

FIG. 13 is a structural schematic view of another array substrate according to an embodiment of the present disclosure;

FIG. 14 is a partial schematic view of the array substrate provided in FIG. 13;

FIG. 15 is a structural schematic cross-sectional view of the array substrate along line P3-P3′ provided in FIG. 13;

FIG. 16 is a structural schematic view of another array substrate according to an embodiment of the present disclosure;

FIG. 17 is a partial schematic view of the array substrate provided in FIG. 16;

FIG. 18 is another partial schematic view of the array substrate provided in FIG. 16;

FIG. 19 is a structural schematic cross-sectional view of the array substrate along line P4-P4′ provided in FIG. 17; and

FIG. 20 is a structural schematic view of a display panel according to an embodiment of the present disclosure.

### DETAILED DESCRIPTION OF THE EMBODIMENTS

The present disclosure is to be described further in detail below with reference to the drawings and embodiments. It can be understood that specific embodiments described herein are used merely to explain the present disclosure, rather than limit the present disclosure. It should be additionally noted that, for ease of description, only some but not all structures related to the present disclosure are shown in the drawings.

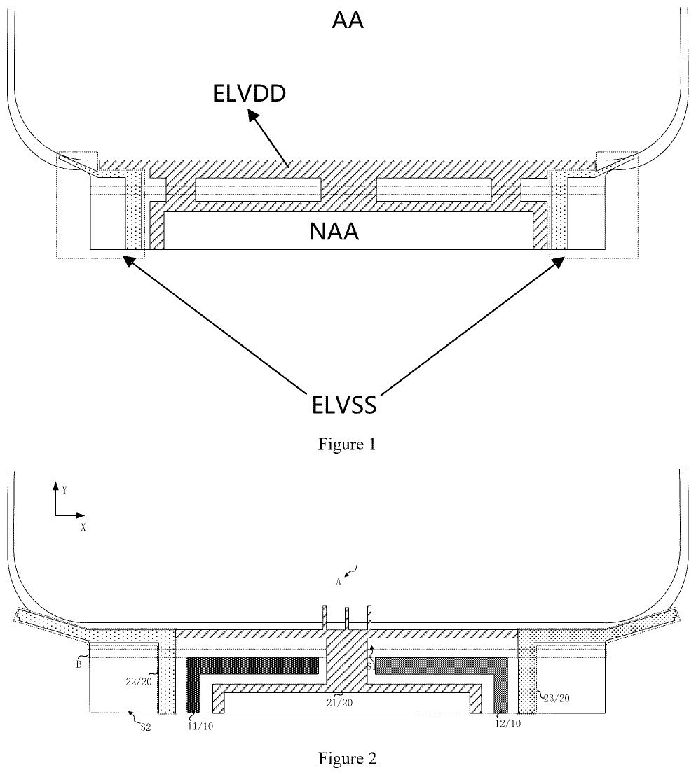

FIG. 1 is a partial structural schematic view of an array substrate provided in the related art. As shown in FIG. 1, the array substrate includes an active area AA and a lower bezel area NAA, and a first power signal line ELVDD extends from the lower bezel area NAA to the active area AA to provide a first power signal to at least one pixel in the active area AA. A second power signal line ELVSS extends from two sides of the lower bezel area NAA to side bezel areas on both sides of the active area AA and is coupled to the active area AA for providing a second power signal to the pixel in the active area AA. When the second power signal line ELVSS extends from both sides of the lower bezel area NAA to the side bezel areas on both sides of the active area AA, the second power signal line ELVSS needs to pass through rounded corner areas between the side bezel areas and the lower bezel area NAA. When the bezel area of the array substrate is relatively narrow, the width of the rounded corner area is narrow. As a result, the line width of the second power signal line ELVSS is also relatively narrow due to the limitation imposed by the width of the rounded corner area, so that the resistance of the second power signal line ELVSS is relatively large. When the second power signal line ELVSS transmits the second power signal, overheating is likely to occur in the rounded corner area.

In view of the above problem, the embodiments of the present disclosure provide an array substrate. By configuring the second power signal transmission structure to include a third structure extending to the active area and disposed between the first structure and the second structure, when the second power signal is transmitted through the third structure to the active area, the transmission of the second power signal through the rounded corner area can be prevented, and the line width of the second power signal transmission structure is prevented from being limited by the rounded corner area, thereby alleviating the overheating phenomenon in the rounded corner arca.

Specifically, FIG. 2 is a structural schematic view of an array substrate according to an embodiment of the present disclosure. As shown in FIG. 2, the array substrate includes an active area A, a first area S1, a bendable area B and a second area S2 that are arranged in a second direction Y; and the array substrate further includes a first power signal transmission structure 10 and a second power signal transmission structure 20. In the second area S2, the first power signal transmission structure 10 includes a first structure 11 and a second structure 12 that are insulated from each other. The first structure 11 and the second structure 12 are arranged in a first direction X. The second power signal transmission structure 20 includes a third structure 21. A part of the third structure 21 located in the second area S2 is disposed between the first structure 11 and the second structure 12, and the third structure 21 extends in the second direction Y to the active area A. The second direction Y intersects the first direction X.

Specifically, the first power signal transmission structure 10 may be configured to transmit a first power signal. By way of example, the active arca A is provided with a pixel including a light-emitting device and a pixel circuit, the pixel circuit being connected to the light-emitting device for providing a drive current for the light-emitting device. The first power signal may be a signal output to a power input end of the pixel circuit and is configured to provide a power voltage to the pixel circuit. The second power signal transmission structure 20 may be configured to transmit a second power signal. By way of example, the second power signal may be a signal output to a cathode of the light-emitting device and is configured to provide a cathode potential to the light-emitting device.

The bendable area B is a region where the display panel is bent, and the second area S2 is disposed on a side of the bendable area B away from the active area A. When the display panel is bent in the bendable area B, the second area S2 is bent to a back side of the display panel. The first direction X may be a row direction of the display panel, and the second direction Y may be a column direction of the display panel. In the second area S2, the first structure 11 and the second structure 12 are arranged in the first direction X, and the first power signal input at the end of the second area S2 away from the bendable area B can be transmitted through the first structure 11 and the second structure 12 simultaneously, so that the transmission reliability of the first power signal can be increased.

The third structure 21 is configured to transmit at least part of the second power signal to the active area A. Specifically, the part of the third structure 21 located in the second area S2 is disposed between the first structure 11 and the second structure 12 and is insulated from the first structure 11 and the second structure 12, so that the second power signal input at the end of the second area S2 away from the bendable area B can be transmitted through the third structure 21 to the active area A. By way of example, the second area S2 is provided with two signal transmission layers connected in parallel, and the first structure 11, the second structure 12 and the part of the third structure 21 located in the second area S2 may each be formed by two signal transmission layers to ensure the signal transmission reliability of the first structure 11, the second structure 12 and the third structure 21. By disconnecting both the first structure 11 and the second structure 12 from the part of the third structure 21 located in the second area S2, the first structure 11 and the second structure 12 can be both insulated from the part of the third structure 21 located in the second area S2 to ensure independent transmission of the first power signal and the second power signal.

The array substrate further includes a first side non-active area and a second side non-active area. The first side non-active area, the active area A and the second side non-active area are arranged in the first direction X. A first rounded corner area is provided at the connection between the first side non-active area and the first area S1, and a second rounded corner area is provided at the connection between the second side non-active area and the first area S1. The third structure 21 extends directly from the bendable area B and the first area S1 between the first structure 11 and the second structure 12 to the active area A when extending in the second direction Y to the active area A, so that the second power signal transmission structure 20 can be prevented from passing through the first rounded corner area and the second rounded corner area, thereby preventing the line width of the second power signal transmission structure from being limited by the rounded corner area, and alleviating the overheating phenomenon in the rounded corner area.

According to the embodiment, the second power signal transmission structure is configured to include a third structure, where the part of the third structure located in the second area is disposed between the first structure and the second structure, and the third structure may extend to the active area. As a result, when the second power signal is transmitted through the third structure to the active area, the transmission of the second power signal through the rounded corner area can be prevented, and the line width of the second power signal transmission structure is prevented from being limited by the rounded corner area, thereby alleviating the overheating phenomenon in the rounded corner area.

Still referring to FIG. 2, the second power signal transmission structure 20 further includes a fourth structure 22 and a fifth structure 23. The fourth structure 22 is disposed on a side of the first structure 11 away from the third structure 21, and the fifth structure 23 is disposed on a side of the second structure 12 away from the third structure 21. The third structure 21, the fourth structure 22 and the fifth structure 23 are connected in the first area S1.

Specifically, the array substrate further includes a first side non-active area and a second side non-active area. The first side non-active area, the active area A and the second side non-active area are arranged in the first direction X. A first rounded corner area is provided at the connection between the first side non-active area and the first area S1, and a second rounded corner area is provided at the connection between the second side non-active area and the first area S1. The fourth structure 22 may extend from the second area S2 to the first area S1 and extend through the first rounded corner area to the first side non-active area, and the second power signal input from the end of the second area S2 away from the bendable area B may also be transmitted through the fourth structure 22 to the first side non-active area and coupled to the active area A. The fifth structure 23 may extend from the second area S2 to the first area S1 and extend through the second rounded corner area to the second side non-active area, and the second power signal input from the end of the second area S2 away from the bendable area B may also be transmitted through the fifth structure 23 to the second side non-active arca and coupled to the active area A. Moreover, the fourth structure 22 and the fifth structure 23 may be connected in the non-active area on the side of the active area A away from the first area S1, achieving a multi-directional input of the second power signal in the active area A.

When the third structure 21, the fourth structure 22 and the fifth structure 23 are connected in the first area S1, the second power signal can be transmitted through the fourth structure 22 and the fifth structure 23 to the active area A, and can also be transmitted through the third structure 21 to the active area A to reduce the equivalent impedance on a transmission path of the second power signal. Moreover, the third structure 21 can shunt the second power signal transmitted through the fourth structure 22 and the fifth structure 23, and can alleviate the overheating phenomenon of the fourth structure 22 and the fifth structure 23, thereby alleviating the overheating phenomenon at the fourth structure 22 and the fifth structure 23.

In some embodiments, the second area S2 is provided with two signal transmission layers connected in parallel, a part of the fourth structure 22 located in the second area S2 and a part of the fifth structure 23 located in the second area S2 may each be formed by two signal transmission layers to ensure the signal transmission reliability. Moreover, by disconnecting the part of the fourth structure 22 located in the second area S2 from the first structure 11 and the part of the fifth structure 23 located in the second area S2 from the second structure 12, the part of the fourth structure 22 located in the second area S2 can be insulated from the first structure 11, and the part of the fifth structure 23 located in the second area S2 can be insulated from the second structure 12, to ensure independent transmission of the first power signal and the second power signal.

Still referring to FIG. 2, in some embodiments, the third structure 21, the fourth structure 22, and the fifth structure 23 are connected in parallel.

Specifically, when the third structure 21, the fourth structure 22 and the fifth structure 23 are connected in parallel, the second power signal can be transmitted through the fourth structure 22 and the fifth structure 23 to the active area A, and can also be transmitted through the third structure 21 to the active area A to reduce the equivalent impedance on a transmission path of the second power signal. Moreover, the third structure 21 can shunt the second power signal transmitted through the fourth structure 22 and the fifth structure 23, and can alleviate the overheating phenomenon of the fourth structure 22 and the fifth structure 23, thereby alleviating the overheating phenomenon at the fourth structure 22 and the fifth structure 23.

According to the embodiment, by configuring the second power signal transmission structure to include the third structure, the third structure may extend to the active area, so that the second power signal can be transmitted through the third structure to the active area, and also through the fourth structure and the fifth structure to the active area. In this case, the third structure is connected in parallel with the fourth structure and the fifth structure, the equivalent impedance of the second power signal transmission structure can be reduced, and the third structure can shunt the second power signal on the fourth structure and the fifth structure, thereby alleviating the overheating phenomenon of the fourth structure and the fifth structure when transmitting the second power signal, and alleviating the overheating phenomenon in the rounded corner area of the display panel.

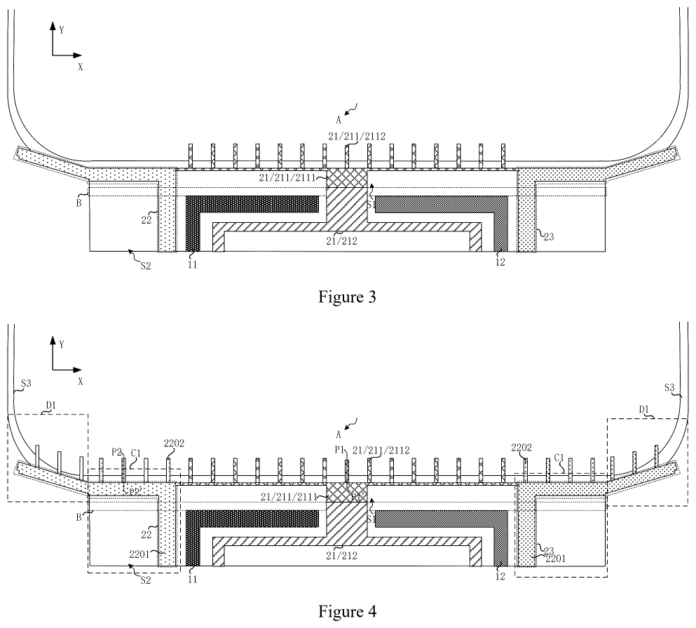

FIG. 3 is a structural schematic view of another array substrate according to an embodiment of the present disclosure. As shown in FIG. 3, the third structure 21 includes a first part 211 and a second part 212. The first part 211 is arranged in the first arca S1, and the second part 212 is arranged in the bendable area B and the second area S2. The first part 211 includes a first main portion 2111 and at least one first branch portion 2112. The first main portion 2111 extends in the first direction X and is connected to the fourth structure 22 and the fifth structure 23, and the first branch portion 2112 extends in the second direction Y to the active arca A.

Specifically, the first part 211 and the second part 212 may be at least partially disposed in the same layer. The second part 212 extends from the second area S2 to the bendable area B, such that the second power signal is transmitted through the second part 212 to the bendable area B. The first part 211 is connected to the second part 212, while the first main portion 2111 extends in the first direction X and is connected to the fourth structure 22 and the fifth structure 23 arranged on two sides, so that transmission reliability of the second power signal can be further increased. The first branch portion 2112 extends in the second direction Y to the active area A such that the second power signal is transmitted through the first branch portion 2112 to the active area A, so that the second power signal can be transmitted through the third structure 21 to the active arca A, realizing a parallel connection of the third structure 21 with the fourth structure 22 and the fifth structure 23, enabling the third structure 21 to shunt the second power signal, thereby alleviating the overheating phenomenon of the fourth structure 22 and the fifth structure 23.

Still referring to FIG. 3, a plurality of first branch portions 2112 may be included. Different first branch portions 2112 may correspond to different pixel columns within the active area A, to provide the second power signal for different pixel columns. By way of example, the first branch portions 2112 may provide the second power signal for pixel columns disposed corresponding to the first main portion 2111.

FIG. 4 is a structural schematic view of another array substrate according to an embodiment of the present disclosure. As shown in FIG. 4, the array substrate further includes a third area S3, the third area S3 and the active area A being arranged in the first direction X. The first area S1 includes a rounded corner area DI and a bezel area C1, the rounded corner area D1 being arranged between the third area S3 and the bezel area C1. In the bezel area C1, at least one of: the fourth structure 22 and the fifth structure 23 includes a second main portion 2201 and at least one second branch portion 2202. The second main portion 2201 extends in the first direction X and is connected to the first main portion 2111. The second branch portion 2202 extends in the second direction Y to the active arca A.

Specifically, FIG. 4 exemplarily shows that the fourth structure 22 and the fifth structure 23 both include the second main portion 2201 and the second branch portion 2202, the second main portion 2201 extending in the first direction X and being connected to the first branch portion 2111 such that the third structure 21 is connected to the fourth structure 22 and the fifth structure 23. The second branch portion 2202 extends in the second direction Y to the active area A, so that the fourth structure 22 can also transmit the second power signal to the active area A, adding an additional transmission path for the second power signal, so that an additional parallel transmission structure can be further added for the second power signal, further reducing the equivalent impedance of the second power signal transmission structure 20, adding an additional shunt path of the second power signal, thereby further alleviating the overheating phenomenon of the fourth structure 22 and the fifth structure 23 when transmit the second power signal, and alleviating the overheating phenomenon of the rounded corner area of the display panel.

Still referring to FIG. 4, a plurality of second branch portions 2202 may be included. Different second branch portions 2202 may correspond to different pixel columns within the active area A, to provide the second power signal for different pixel columns. By way of example, the second branch portions 2202 may provide the second power signal for pixel columns disposed corresponding to the second main portion 2201.

In some embodiments, the number of first branch portions 2112 and the number of second branch portions 2202 are equal to the number of sub-pixels in one row within the active area A.

Specifically, both the first branch portion 2112 and the second branch portion 2202 are branches of the second power signal transmission structure 20 extending to the active area A. By setting the number of first branch portions 2112 and the number of second branch portions 2202 to be equal to the number of sub-pixels in one row within the active area A, the first branch portion 2112 and the second branch portion 2202 are respectively connected to a column of pixels, so that the consistency of second power signals received by different pixels can be improved, thereby facilitating an improvement in the display uniformity of the display panel.

In some embodiments, the active area A includes a signal transmission layer configured to provide a drive signal to at least one pixel in the active area A. At least part of the first part 211 is disposed in the same layer as the signal transmission layer.

Specifically, the active area A is provided at a pixel circuit layer and configured to form devices and signal lines in the pixel circuit. By way of example, the pixel circuit layer may include a substrate, and a first metal layer, a second metal layer, a third metal layer and a fourth metal layer that are disposed on the substrate. The first metal layer may be configured to form a gate of a transistor in the pixel circuit; the second metal layer may be configured to form an electrode of a capacitor in the pixel circuit; the third metal layer may be configured to form a source and a drain of the transistor and a signal line such as a data signal line for providing drive signals to the source and the drain; and the fourth metal layer may be configured to form another signal line such as a power signal line for providing a drive signal to the pixel circuit. The signal transmission layer may include the third metal layer and the fourth metal layer and is configured to provide the drive signal to the pixel.

The first part 211 may include at least one conductive layer. The at least one conductive layer may be disposed in the same layer as any signal transmission layer, avoiding the need for additional film layers, and facilitating the simplification of the structure and the fabrication process of the array substrate. By way of example, when the at least one conductive layer is disposed in the same layer as a signal transmission layer, the first part 211 may be formed in synchronization with the first area S1 when the signal transmission layer is formed. By way of example, when the first part 211 of the third structure 21 located in the first area S1 is a single conductive layer, the first part 211 may be disposed in the same layer as the third metal layer, or may be disposed in the same layer as the fourth metal layer.

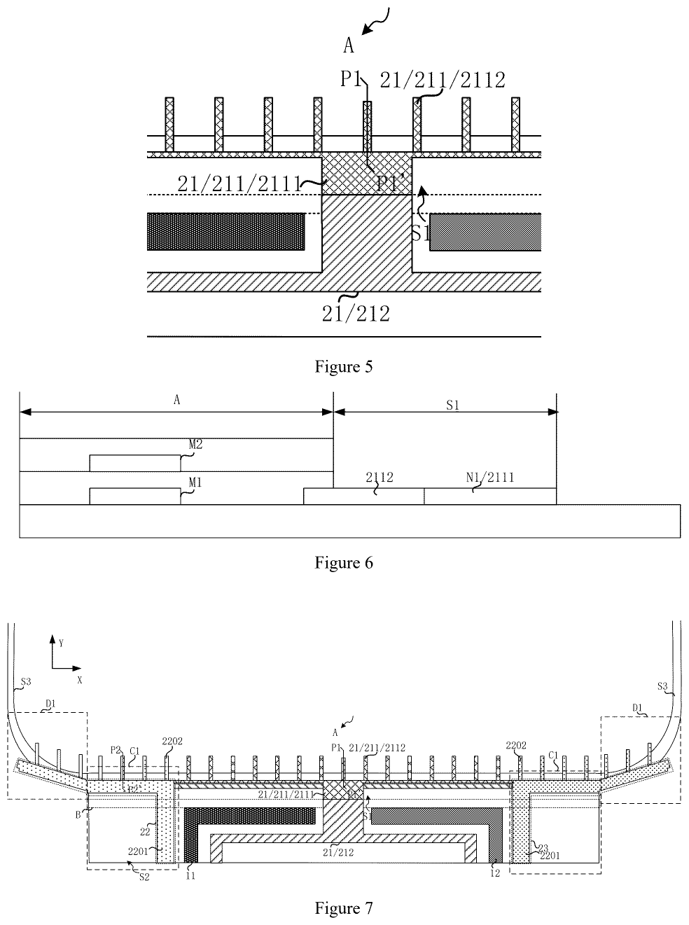

In some embodiments, FIG. 5 is a partial schematic view of the array substrate provided in FIG. 4, and FIG. 6 is a structural schematic cross-sectional view taken along line P1-P1′ in FIG. 5. As shown in FIGS. 5 and 6, the signal transmission layer includes a first signal transmission layer Ml and a second signal transmission layer M2, the second signal transmission layer M2 being disposed on a side of the first signal transmission layer M1 close to a light exit surface; and the first main portion 2111 includes a first conductive layer N1, the first conductive layer N1 being disposed in the same layer as the first signal transmission layer M1 or the second signal transmission layer M2.

Specifically, when the first main portion 2111 includes one conductive layer, i.e., the first conductive layer N1, the first conductive layer N1 may be disposed in the same layer as the first signal transmission layer M1 or may be disposed in the same layer as the second signal transmission layer M2, thus avoiding the need for additional film layers, and simplifying the structure of the array substrate. The material of the first conductive layer N1 may be the same as the material of the signal transmission layer disposed in the same layer. In the fabrication process of the array substrate, the first main portion 2111 can be formed synchronously in the first area S1 by a patterning process during the forming process of the signal transmission layer, simplifying the fabrication process of the array substrate. By way of example, when the first conductive layer N1 is disposed in the same layer as the first signal transmission layer M1, the first main portion 2111 may be synchronously formed in the first area S1 by a patterning process when the first signal transmission layer M1 is formed.

The first main portion 2111 extends in the first direction X. When the first power signal transmission structure 10 extends to the active area A and is configured to provide the first power signal to the active area A, in the first area S1, the first main portion 2111 is disposed in a different layer from the first power signal transmission structure 10, preventing a cross short circuit between a part of the first power signal transmission structure 10 located in the first area S1 and the first main portion 2111, and ensuring the transmission reliability of the first power signal and the second power signal. By way of example, when the first conductive layer N1 is disposed at the first signal transmission layer M1, the part of the first power signal transmission structure 10 located in the first area S1 may be disposed at the second signal transmission layer M2. When the first conductive layer N1 is provided at the second signal transmission layer M2, the part of the first power signal transmission structure 10 located in the first area S1 may be provided at the first signal transmission layer M1.

It should be noted that FIG. 6 exemplarily shows that the first conductive layer N1 is disposed in the same layer as the first signal transmission layer M1. In some embodiments, the first conductive layer N1 may be disposed in the same layer as the second signal transmission layer M2. This is not limited here.

Still referring to FIG. 6, the first branch portion 2112 is disposed in the same layer as the first main portion 2111.

Specifically, when the first branch portion 2112 is disposed in the same layer as the first main portion 2111, the first branch portion 2112 can be in contact connection with the first main portion 2111, so that the process for connecting the first branch portion 2112 to the first main portion 2111 can be simplified. When the material of the first branch portion 2112 is the same as the material of the first main portion 2111, the first branch portion 2112 and the first main body portion 2111 may be formed simultaneously in the same process, further simplifying the fabrication process of the array substrate.

In some embodiments, the first conductive layer includes a first lower layer, a first middle layer and a first upper layer that are disposed in a stack. The first lower layer, the first middle layer and the first upper layer are conductive layers.

Specifically, the first conductive layer may include a first lower layer, a first middle layer and a first upper layer that are disposed in a stack, and by configuring the first middle layer to have good conductive performance, the effectiveness of signal transmission of the first conductive layer can be ensured. Moreover, the first lower layer and the first upper layer are configured to protect the first middle layer, so that the signal transmission reliability of the first conductive layer can be improved.

In some embodiments, the first lower layer and the first upper layer are made of titanium; and the first middle layer is made of aluminum.

Specifically, the first conductive layer may be of a titanium/aluminum/titanium structure. Aluminum has good conductive performance and is used to ensure the effectiveness of transmission of the second power signal. The first lower layer and the first upper layer may cover the first middle layer, so that the aluminum material of the first middle layer from can be prevented being oxidized, thereby ensuring the signal transmission reliability of the first middle layer. In addition, when organic material layers are provided on two sides of the first conductive layer, titanium in the first lower layer and the first upper layer can prevent interfacial delamination caused by direct contact between the aluminum in the first middle layer and the organic material layers.

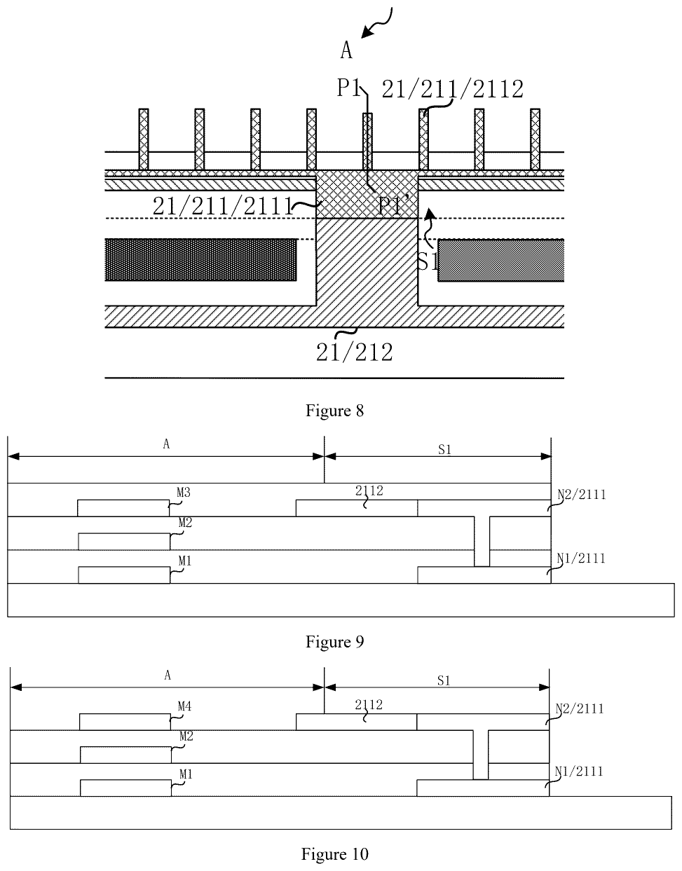

In some embodiments, FIG. 7 is a structural schematic view of another array substrate according to an embodiment of the present disclosure, FIG. 8 is a partial schematic view of the array substrate provided in FIG. 7, and FIG. 9 is a structural schematic cross-sectional view taken along line P1-P1′ in FIG. 8. As shown in FIGS. 7 to 9, the signal transmission layer further includes a third signal transmission layer M3, the third signal transmission layer M3 being disposed on a side of the second signal transmission layer M2 close to the light exit surface; and the first main portion 2111 further includes a second conductive layer N2, the first conductive layer N1 being connected to the second conductive layer N2, and the second conductive layer N2 being disposed in the same layer as the third signal transmission layer M3.

Specifically, in FIG. 7, the first main portion 2111 may include two conductive layers, namely a first conductive layer N1 and a second conductive layer N2. The second conductive layer N2 is connected to the first conductive layer N1, so that the signal transmission reliability of the first main portion 2111 can be improved.

Preferably, the first conductive layer N1 and the second conductive layer N2 are connected in parallel, so that the equivalent impedance of the first conductive layer N1 when transmitting the second power signal can be reduced. When the first main portion 2111 is connected in parallel with the fourth structure 22 and the fifth structure 23, the equivalent impedance of the second power signal transmission structure 20 can be further reduced, thereby further alleviating the overheating phenomenon in the rounded corner area of the display panel.

In some embodiments, a fifth metal layer is further provided on the array substrate for forming a signal line providing a drive signal to the pixel circuit. By way of example, the third signal transmission layer M3 may be the fifth metal layer. In this case, the first main portion 2111 may be of a structure in which the third metal layer and the fifth metal layer are connected in parallel, such that the second power signal transmission structure 20 is connected in parallel with the fifth metal layer via the third metal layer for lateral transmission. It is also possible that the first main portion is of a structure in which the fourth metal layer and the fifth metal layer are connected in parallel, such the second power signal transmission structure 20 is connected in parallel with the fifth metal layer via the fourth metal layer for lateral transmission. When the second conductive layer N2 is disposed in the same layer as the third signal transmission layer M3, the need for additional film layers can be avoided while reducing the equivalent impedance of the first main portion 2111, thereby simplifying the structure of the array substrate. When the first conductive layer N1 of the first main portion 2111 is disposed in the same layer as the first signal transmission layer M1 or the second signal transmission layer M2, the part of the first power signal transmission structure 10 located in the first area S1 may be disposed at least partially in the same layer as the second signal transmission layer M2 or the first signal transmission layer M1, preventing a cross short circuit between the part of the first power signal transmission structure 10 located in the first area S1 and the first main portion 2111. When the first main portion 2111 further includes the second conductive layer N2, the second conductive layer N2 is disposed in the same layer as the third signal transmission layer M3, so that the second conductive layer N2 is disposed in a different layer from the part of the first power signal transmission structure 10 located in the first area S1, thereby preventing a cross short circuit between the second conductive layer N2 and the part of the first power signal transmission structure 10 located in the first area S1, and ensuring the transmission reliability of the first power signal and the second power signal.

Still referring to FIG. 9, the first branch portion 2112 is disposed in the same layer as the third signal transmission layer M3.

Specifically, the first branch portion 2112 may include one conductive layer. When the first branch portion 2112 and the third signal transmission layer M3 are disposed in the same layer, the first branch portion 2112 may be in contact connection with the second conductive layer N2, simplifying the difficulty in connecting the first branch portion 2112 to the first main portion 2111. The material of the first branch portion 2112 may be the same as the material of the second conductive layer N2, and the first branch portion 2112 may be formed simultaneously by a patterning process while the second conductive layer N2 is being fabricated during the fabrication of the array substrate, simplifying the fabrication process of the array substrate. Moreover, when the first branch portion 2112 is disposed in the same layer as the third signal transmission layer M3, the first branch portion 2112 is disposed in a different layer from the part of the first power signal transmission structure 10 located in the first area S1, reducing the probability of a short circuit between the first branch portion 2112 and the first power signal transmission structure 10, and ensuring the transmission reliability of the first power signal and the second power signal. By way of example, when the third signal transmission layer M3 is a fifth metal layer in the related art, the first branch portion 2112 is disposed in the same layer as the fifth metal layer and may be formed in the same process as the fifth metal layer.

It should be noted that in other embodiments, the first branch portion 2112 may be disposed in the same layer as the first conductive layer N1. In this case, the first branch portion 2112 needs to be disposed in a different layer from the part of the first power signal transmission structure 10 located in the first area S1, thereby reducing the probability of a short circuit between the part of the first power signal transmission structure 10 located in the first area S1 when extending to the active area A and the first branch portion 2112 when extending to the active area A, and ensuring the transmission reliability of the first power signal and the second power signal.

In some embodiments, the second conductive layer includes a second lower layer, a second middle layer and a second upper layer that are disposed in a stack. The second lower layer, the second middle layer and the second upper layer are conductive layers.

Specifically, the second conductive layer may include a second lower layer, a second middle layer and a second upper layer that are disposed in a stack, and by configuring the second middle layer to have good conductive performance, the effectiveness of signal transmission of the second conductive layer can be ensured. Moreover, the second lower layer and the second upper layer are configured to protect the second middle layer, so that the signal transmission reliability of the second conductive layer can be improved.

In some embodiments, the second lower layer and the second upper layer are made of titanium; and the second middle layer is made of aluminum.

Specifically, the second conductive layer may be of a titanium/aluminum/titanium structure. Aluminum has good conductive performance and is used to ensure the effectiveness of transmission of the second power signal. The second lower layer and the second upper layer may cover the second middle layer, so that the aluminum material of the second middle layer from can be prevented being oxidized, thereby ensuring the signal transmission reliability of the second middle layer. In addition, when organic material layers are provided on two sides of the second conductive layer, titanium in the second lower layer and the second upper layer can prevent interfacial delamination caused by direct contact between the aluminum in the second middle layer and the organic material layers.

In some embodiments, FIG. 10 is a structural schematic cross-sectional view of another array substrate according to an embodiment of the present disclosure. As shown in FIG. 10, the active area A includes an anode layer M4. The anode layer M4 is disposed on a side of the second signal transmission layer M2 close to the light exit surface, and the anode layer M4 is configured to form at least one anode of the pixel in the active area A. The first main portion 2111 further includes a second conductive layer N2, the first conductive layer N1 being connected to the second conductive layer N2, and the second conductive layer N2 being disposed in the same layer as the anode layer M4.

Specifically, the array substrate may be provided with the anode layer M4, the anode layer being disposed on the side of the signal transmission layer close to the light exit surface, configured to form the anode of a light-emitting device in the pixel, and connected to the pixel circuit, such that the pixel circuit provides a drive signal for the anode of the light-emitting device. When the second conductive layer N2 is disposed in the same layer as the anode layer M4, the need for additional film layers can be avoided while improving the signal transmission reliability, thereby simplifying the structure of the array substrate.

The first conductive layer N1 and the second conductive layer N2 are connected in parallel. In this case, the first main portion 2111 may be of a structure in which the third metal layer and the anode layer M4 are connected in parallel, such that the second power signal transmission structure 20 is connected in parallel with the anode layer M4 via the third metal layer for lateral transmission. It is also possible that the first main portion is of a structure in which the fourth metal layer and the anode layer M4 are connected in parallel, such the second power signal transmission structure 20 is connected in parallel with the anode layer M4 via the fourth metal layer for lateral transmission. The first main portion 2111 is connected in parallel with the anode layer M4 by providing the first conductive layer N1, and he need for additional film layers can be avoided while reducing the equivalent impedance of the first main portion 2111, thereby simplifying the structure of the array substrate. When the first power signal transmission structure 10 is disposed in the same layer as the first signal transmission layer M1 or the second signal transmission layer M2, the second conductive layer N2 is disposed in the same layer as the anode layer M4, so that the second conductive layer N2 is disposed in a different layer from the part of the first power signal transmission structure 10 located in the first area S1, thereby preventing a cross short circuit between the second conductive layer N2 and the part of the first power signal transmission structure 10 located in the first area S1, and ensuring the transmission reliability of the first power signal and the second power signal.

In some embodiments, the first branch portion 2112 is disposed in the same layer as the anode layer M4.

Specifically, the first branch portion 2112 may include one conductive layer. Similar to the above process, when the second conductive layer N2 is disposed in the same layer as the anode layer M4, the first branch portion 2112 may be disposed in the same layer as the anode layer M4, such that the first branch portion 2112 is in contact connection with the second conductive layer N2, thereby simplifying the difficulty in connecting the first branch portion 2112 to the first main portion 2111. The material of the first branch portion 2112 may be the same as the material of the second conductive layer N2, and the first branch portion 2112 may be formed simultaneously by a patterning process while the second conductive layer N2 is being fabricated during the fabrication of the array substrate, simplifying the fabrication process of the array substrate. Moreover, the first branch portion 2112 may be disposed in a different layer from the part of the first power signal transmission structure 10 located in the first area S1, reducing the probability of a short circuit between the first branch portion 2112 and the first power signal transmission structure 10, and ensuring the transmission reliability of the first power signal and the second power signal.

It should be noted that in other embodiments, the first branch portion 2112 may be disposed in the same layer as the first conductive layer N1; and when the part of the first power signal transmission structure 10 located in the first area S1 is disposed in a different layer from the first conductive layer N1, the first branch portion 2112 is disposed in a different layer from the part of the first power signal transmission structure 10 located in the first area S1, so that the probability of a short circuit between the two can be reduced, thereby ensuring the transmission reliability of the first power signal and the second power signal.

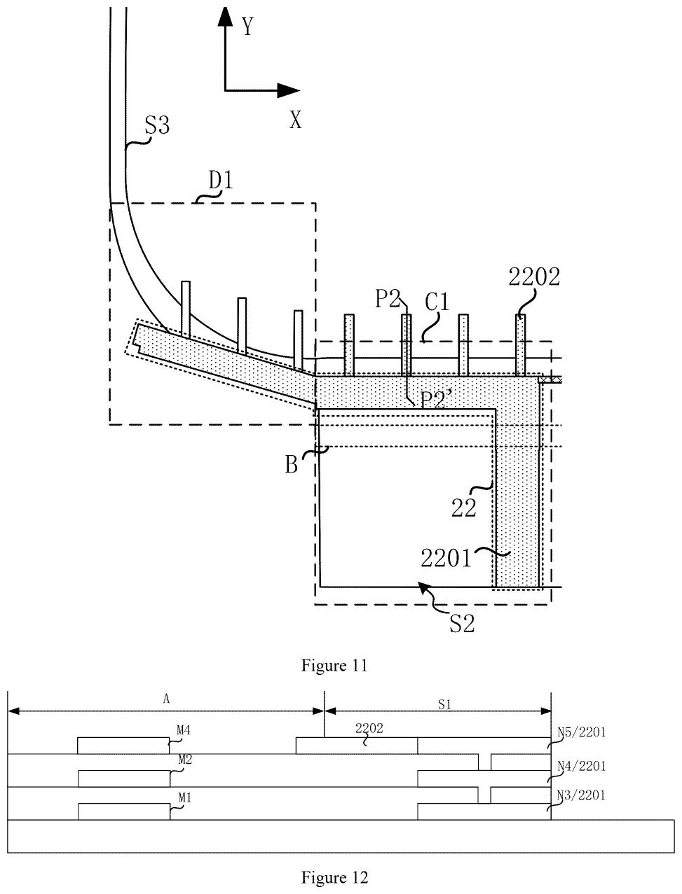

Based on the above embodiments, FIG. 11 is another partial schematic view of the array substrate provided in FIG. 4, and FIG. 12 is a structural schematic cross-sectional view taken along a line P2-P2′ in FIG. 11. As shown in FIGS. 11 and 12, the array substrate further includes a third area S3. The third area S3 and the active area A are arranged in the first direction X. The first area S1 includes a rounded corner arca D1 and a bezel area C1, the rounded corner area D1 being arranged between the third area S3 and the bezel area C1. In the bezel area C1, at least one of: the fourth structure 22 and the fifth structure 23 include a third conductive layer N3 and a fourth conductive layer N4 that are connected in parallel. The third conductive layer N3 is disposed in the same layer as the first signal transmission layer M1, and the fourth conductive layer N4 is disposed in the same layer as the second signal transmission layer M2.

Specifically, at least one of: the fourth structure 22 and the fifth structure 23 may include the third conductive layer N3 and the fourth conductive layer N4 that are connected in parallel. By connecting the third conductive layer N3 and the fourth conductive layer N4 in parallel, the equivalent impedance of at least one of: the fourth structure 22 and the fifth structure 23 can be reduced to alleviate the overheating phenomenon of at least one of: the fourth structure 22 and the fifth structure 23. In some embodiments, the third conductive layer N3 and the fourth conductive layer N4 may be disposed in the same layers as the first signal transmission layer Ml and the second signal transmission layer M2, respectively, so that the need for additional film layers can be avoided while reducing the equivalent impedance of at least one of: the fourth structure 22 and the fifth structure 23, thereby simplifying the structure of the array substrate. The third conductive layer N3 and the fourth conductive layer N4 may be formed in the same processes as the first signal transmission layer M1 and the second signal transmission layer M2, respectively, so that the fabrication process of the array substrate can be simplified.

In some embodiments, at least one of: the fourth structure 22 and the fifth structure 23 further includes a fifth conductive layer N5. The fifth conductive layer N5 is connected in parallel with the third conductive layer N3 and the fourth conductive layer N4, and the fifth conductive layer N5 is disposed in the same layer as the third signal transmission layer M3 or the anode layer M4.

In this embodiment, at least one of: the fourth structure 22 and the fifth structure 23 may further include the fifth conductive layer N5. When the array substrate includes the third signal transmission layer M3, the fifth conductive layer N5 is disposed in the same layer as the third signal transmission layer M3. When the array substrate includes an anode layer M4, the fifth conductive layer N5 is disposed in the same layer as the anode layer M4. The fifth conductive layer N5 is connected in parallel with the third conductive layer N3 and the fourth conductive layer N4, so that the equivalent impedance of at least one of: the fourth structure 22 and the fifth structure 23 can be further reduced. The fifth conductive layer N5 is disposed in the same layer as the third signal transmission layer M3 or the anode layer M4, so that the need for additional film layers can be avoided, thereby simplifying the structure of the array substrate. The fifth conductive layer N5 may be formed in the same process as the third signal transmission layer M3 or the anode layer M4 that is disposed in the same layer, so that the fabrication process of the array substrate can be simplified. By way of example, when the fifth conductive layer N5 is disposed in the same layer as the third signal transmission layer M3, in which case at least one of: the fourth structure 22 and the fifth structure 23 located in the bezel area C1 may be formed by connecting the first signal transmission layer M1, the second signal transmission layer M2 and the third signal transmission layer M3 in parallel. For example, when the first signal transmission layer M1 is a third metal layer, the second signal transmission layer M2 is a fourth metal layer, and the third signal transmission layer M3 is a fifth metal layer, at least one of: the fourth structure 22 and the fifth structure 23 located in the bezel area C1 is formed by connecting the third metal layer, the fourth metal layer and the fifth metal layer in parallel. When the fifth conductive layer N5 is disposed in the same layer as the anode layer M4, at least one of: the fourth structure 22 and the fifth structure 23 located in the bezel area C1 may be formed by connecting the first signal transmission layer M1, the second signal transmission layer M2 and the anode layer M4 in parallel. For example, when the first signal transmission layer M1 is a third metal layer and the second signal transmission layer M2 is a fourth metal layer, at least one of: the fourth structure 22 and the fifth structure 23 located in the bezel area C1 is formed by connecting the third metal layer, the fourth metal layer and the anode layer M4 in parallel.

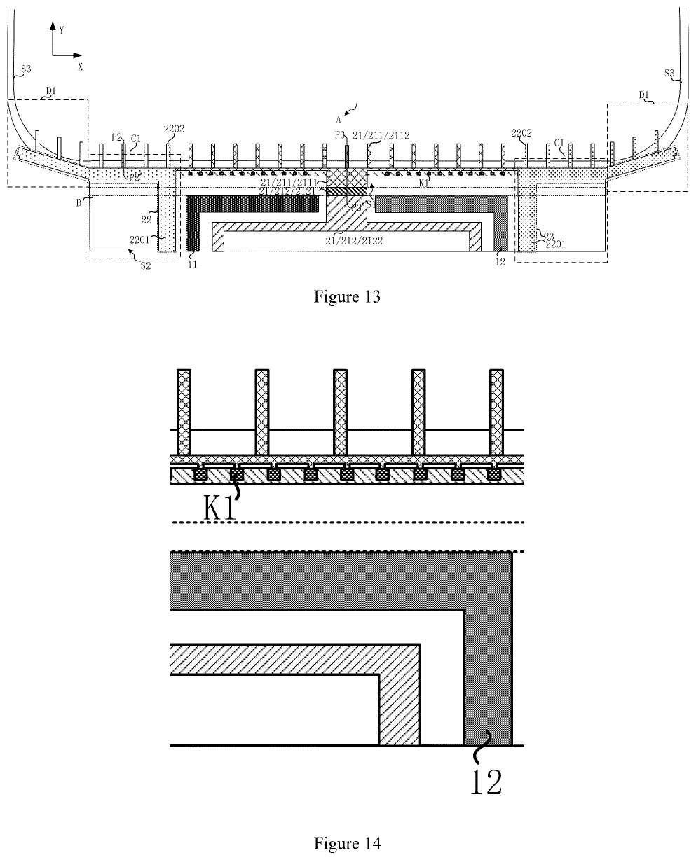

FIG. 13 is a structural schematic view of another array substrate according to an embodiment of the present disclosure, and FIG. 14 is a partial schematic view of the array substrate provided in FIG. 13. As shown in FIGS. 13 and 14, when the first conductive layer N1 is disposed in the same layer as the first signal transmission layer M1, the second signal transmission layer M2 further includes a bridging portion K1. The first conductive layer N1 and the second conductive layer N2 are connected to each other via the bridging portion K1.

Specifically, when the first conductive layer N1 is disposed in the same layer as the first signal transmission layer M1, the second signal transmission layer M2 is provided between the first conductive layer N1 and the second conductive layer N2. When the first conductive layer N1 and the second conductive layer N2 are connected in parallel, they may be connected via the bridging portion K1 of the second signal transmission layer M2, so that the process of connecting the first conductive layer N1 to the second conductive layer N2 can be simplified. By way of example, when the first signal transmission layer M1 is a third metal layer, the first conductive layer N1 is disposed in the same layer as the first signal transmission layer M1, the second signal transmission layer M2 is a fourth metal layer, and the second conductive layer N2 is disposed in the same layer as the anode layer M4, the third metal layer of the first main portion 2111 and the anode layer M4 are bridged by means of the bridging portion K1 of the fourth metal layer, thereby forming a lateral parallel connection of the second power signal transmission structure 20.

It should be noted that when the second signal transmission layer M2 is disposed in the same layer as at least part of the first power signal transmission structure 10, the bridging portion K1 is disconnected from the first power signal transmission structure 10, so that the first conductive layer N1 and the second conductive layer N2 are insulated from the first power signal transmission structure 10.

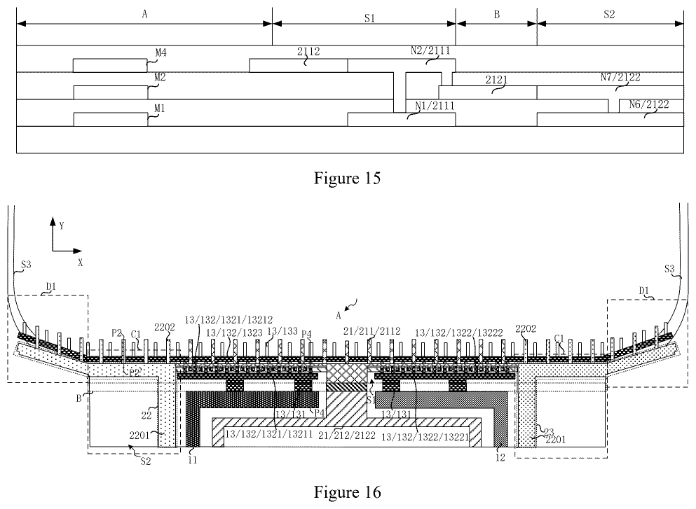

Still referring to FIG. 13, FIG. 15 is a structural schematic cross-sectional view of the array substrate taken along line P3-P3′ provided in FIG. 13. As shown in FIGS. 13 and 15, the second part 212 includes a first sub-part 2121 and a second sub-part 2122. The first sub-part 2121 is disposed in the bendable area B, and the second sub-part 2122 is disposed in the second area S2; and the first sub-part 2121 is disposed in the same layer as part of the signal transmission layer, and the second sub-part 2122 is disposed in the same layer as the signal transmission layer.

Specifically, the first sub-part 2121 may include one conductive layer to ensure the bendability of the bendable area B. When the signal transmission layer includes at least a first signal transmission layer M1 and a second signal transmission layer M2, the first sub-part 2121 may be disposed in the same layer as the first signal transmission layer M1 or the second signal transmission layer M2, so that the structure and the fabrication process of the array substrate can be simplified. The second sub-part 2122 may include at least two conductive layers connected in parallel, not only ensuring the transmission reliability of the first power signal, but also reducing the equivalent resistance of the second sub-part 2122, thereby facilitating the alleviation of the overheating phenomenon of the array substrate. By way of example, when the first signal transmission layer M1 is a third metal layer and the second signal transmission layer M2 is a fourth metal layer, the second power signal transmission structure 20 located in the bendable area B is of a single-layer structure, thereby achieving a single-layer crossover of the second power signal transmission structure 20 in the bendable area B. For example, the second power signal transmission structure 20 located in the bendable area B may be disposed in the same layer as the fourth metal layer.

In some embodiments, the second sub-part 2122 includes a sixth conductive layer N6 and a seventh conductive layer N7 that are connected in parallel. The sixth conductive layer N6 is disposed in the same layer as the first signal transmission layer M1, and the seventh conductive layer N7 is disposed in the same layer as the second signal transmission layer M2.

Specifically, the sixth conductive layer N6 and the seventh conductive layer N7 are connected in parallel, so that the transmission reliability of the first power signal can be ensured, while the equivalent resistance of the second sub-part 2122 can be reduced, thereby facilitating the alleviation of the overheating phenomenon of the array substrate. The sixth conductive layer N6 is disposed in the same layer as the first signal transmission layer M1, and the seventh conductive layer N7 is disposed in the same layer as the second signal transmission layer M2, so that the need for additional film layers can be avoided, thereby simplifying the structure of the array substrate. When the material of the sixth conductive layer N6 is the same as that of the first signal transmission layer M1, the sixth conductive layer N6 and the first signal transmission layer M1 may be formed in the same process. When the material of the seventh conductive layer N7 is the same as that of the second signal transmission layer M2, the seventh conductive layer N7 and the second signal transmission layer M2 may be formed in the same process, thereby simplifying the fabrication process of the array substrate. By way of example, when the first signal transmission layer M1 is a third metal layer and the second signal transmission layer M2 is a fourth metal layer, the second power signal transmission structure 20 located in the second area S2 is the third metal layer and the fourth metal layer that are connected in parallel.

Based on the above embodiments, the first sub-part 2121 is disposed in a different layer from the first part 211.

Specifically, the bendable area B may include one conductive layer for forming a signal transmission structure. When the first power signal transmission structure 10 extends from the second area S2 to the active area A, a part of the first power signal transmission structure 10 located in the bendable area B is formed by the conductive layer provided in the bendable area B. When the part of the first power signal transmission structure 10 located in the first area S1 is disposed in the same layer as the part thereof located in the bendable area B, the first sub-part 2121 is disposed in the same layer as the part of the first power signal transmission structure 10 located in the first area S1, in which case the first sub-part 2121 may be disposed in a different layer from the first part 211, i.e., the first sub-part 2121 in the first area S1 is routed to another conductive layer, preventing a cross short circuit between the first part 211 and the part of the first power signal transmission structure 10 located in the first area S1, thereby ensuring the transmission reliability of the first power signal and the second power signal. By way of example, when the first signal transmission layer M1 is a third metal layer and the second signal transmission layer M2 is a fourth metal layer, the second power signal transmission structure 20 located in the bendable area B may be disposed at the fourth metal layer, and the second power signal transmission structure 20 located in the first area S1 may be disposed at the third metal layer and the anode layer M4. In this case, from the bendable area B to the first area S1, the second power signal transmission structure 20 may be routed from the fourth metal layer to the third metal layer and the anode layer M4.

Based on the above embodiments, at least one conductive layer of the fourth structure 22 is disposed in the same layer as the first part 211.

Specifically, when the first part 211 includes one conductive layer, the conductive layer may be disposed in the same layer as the first signal transmission layer M1 or the second signal transmission layer M2, and the fourth structure 22 may include at least one conductive layer disposed in the same layer as at least one of: the first signal transmission layer M1 and the second signal transmission layer M2, so that the number of conductive layers required to transmit the first power signal can be reduced, thereby facilitating the simplification of the wiring of the first power signal transmission structure 10 and the second power signal transmission structure 20. When the first part 211 includes two conductive layers, the first conductive layer N1 is disposed in the same layer as the first signal transmission layer M1 or the second signal transmission layer M2, and the second conductive layer N2 is disposed in the same layer as the third signal transmission layer M3 or the anode layer M4. In this case, the fourth structure 22 may include at least two conductive layers, at least one conductive layer of which is disposed in the same layer as at least one of: the first signal transmission layer M1 and the second signal transmission layer M2, and one conductive layer of which may be disposed in the same layer as the third signal transmission layer M3 or the anode layer M4, so that the equivalent impedance of the fourth structure 22 can be reduced, and the wiring of the first power signal transmission structure 10 and the second power signal transmission structure 20 can also be simplified.

In some embodiments, at least one conductive layer of the fifth structure 23 is disposed in the same layer as the first part 211.

Specifically, the film layer arrangement of the fifth structure 23 may be the same as the film layer arrangement of the fourth structure 22, which will not be described here in detail.

In the first direction X, the first structure 11 and the second structure 12 are symmetrically disposed about the third structure 21.

Specifically, the third structure 21 may be disposed on a center line extending in the second direction Y within the active area A, so that the areas on two sides of the third structure 21 to be approximately equal. When the first structure 11 and the second structure 12 are disposed on the two sides of the third structure 21, the available area of the first structure 11 and the second structure 12 can be increased. The first structure 11 and the second structure 12 being symmetrically disposed about the third structure 21 can simplify the wiring arrangement of the first structure 11 and the second structure 12.

In some embodiments, the fourth structure 22 and the fifth structure 23 are symmetrically disposed about the third structure 21 in the first direction X, so that the wiring arrangement of the fourth structure 22 and fifth structure 23 can also be simplified.

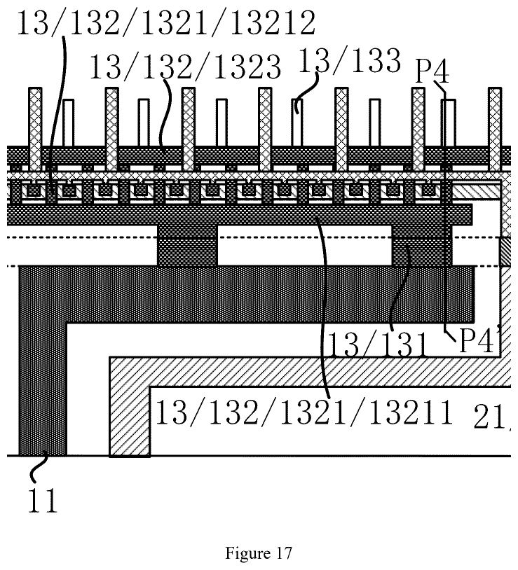

FIG. 16 is a structural schematic view of another array substrate according to an embodiment of the present disclosure, and FIG. 17 is a partial schematic view of the array substrate provided in FIG. 16. As shown in FIGS. 16 and 17, the first power signal transmission structure 10 further includes a sixth structure 13. The sixth structure 13 is disposed in the first area S1 and the bendable area B and extends to the active area A; and the sixth structure 13 is connected to the first structure 11 and the second structure 12.

Specifically, the first structure 11 and the second structure 12 are disposed in the second area S2 and located on two sides of the third structure 21, and parts of the sixth structure 13 located in the first area S1 and the bendable area B may include branches on the two sides of the third structure 21, are connected to the first structure 11 and the second structure 12, respectively, and extend to the active area A. In this way, the first power signal transmitted by the first structure 11 and the second structure 12 is transmitted through the sixth structure 13 to the active area A, so that the first power signal can be transmitted to the active area A.

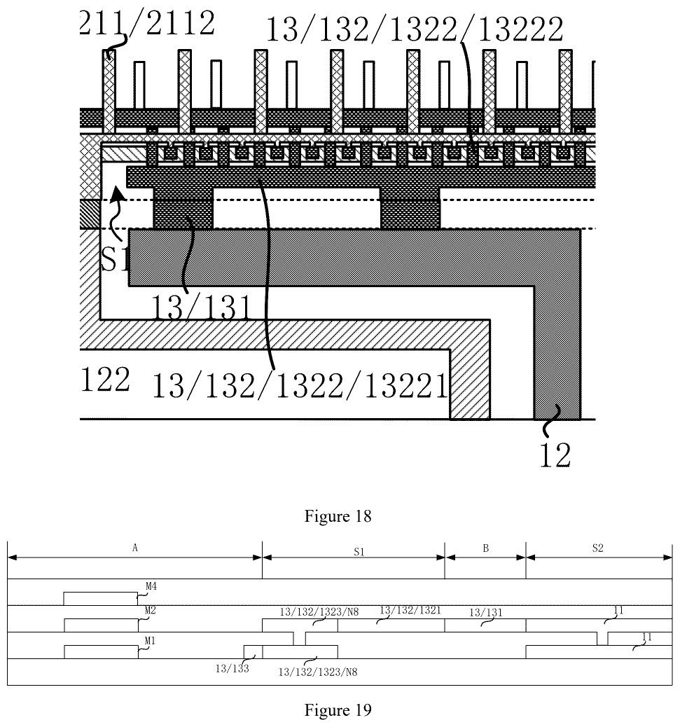

FIG. 18 is another partial schematic view of the array substrate provided in FIG. 16. As shown in FIGS. 17 and 18, the sixth structure 13 includes a third part 131, a fourth part 132 and a fifth part 133. The third part 131 is disposed in the bendable area B, the fourth part 132 is disposed in the first area S1, and the fifth part 133 is disposed in the active area A; and the third part 131 is disposed in the same layer as at least part of the fourth part 132, and the fourth part 132 is disposed in the same layer as at least part of the fifth part 133.

Specifically, the bendable area B has one conductive layer and the third part 131 may include one conductive layer for ensuring the bendability of the bendable area B. By way of example, the third part 131 may be disposed in the same layer as the first signal transmission layer M1 or the second signal transmission layer M2, so that the need for additional film layers can be avoided, thereby simplifying the structure and the fabrication process of the array substrate. For example, when the first signal transmission layer M1 is a third metal layer and the second signal transmission layer M2 is a fourth metal layer, the part of the first power signal transmission structure 10 located in the bendable area B is disposed in the same layer as the fourth metal layer, such that the part of the first power signal transmission structure 10 located in the bendable area B is a single metal layer, i.e., the first power signal transmission structure 10 is routed to the first area S1 by means of the single metal layer spanning the bendable area B. The fourth part 132 may include at least one conductive layer. The at least one conductive layer may be disposed in the same layer as at least one of: the first signal transmission layer M1 and the second signal transmission layer M2, thereby avoiding the need for additional film layers, and simplifying the structure and the fabrication process of the array substrate. For example, when the first signal transmission layer M1 is a third metal layer and the second signal transmission layer M2 is a fourth metal layer, the part of the first power signal transmission structure 10 located in the first area S1 is disposed in the same layer as the fourth metal layer, such that the part of the first power signal transmission structure 10 located in the first arca S1 is a single metal and laterally spans the part of the second power signal transmission structure 20 located in the first area S1. The fifth part 133 may include one conductive layer, s that the wiring difficulty in the active area A can be reduced while ensuring that the first power signal is transmitted to the active arca A. By way of example, the fifth part 133 may be disposed in the same layer as the first signal transmission layer Ml or the second signal transmission layer M2, so that the need for additional film layers can be avoided, thereby simplifying the structure and the fabrication process of the array substrate. For example, when the first signal transmission layer M1 is a third metal layer and the second signal transmission layer M2 is a fourth metal layer, the part of the first power signal transmission structure 10 located in the active area A may be disposed in the same layer as the third metal layer.

In some embodiments, FIG. 19 is a structural schematic cross-sectional view of the array substrate taken along a line P4-P4′ provided in FIG. 17. As shown in FIG. 19, the third part 131 is disposed in the same layer as at least part of the second part 212 of the third structure 21; and the fourth part 132 and the fifth part 133 are disposed in a different layer from at least part of the first part 211 of the third structure 21.

Specifically, the second part 212 of the third structure 21 may include a first sub-part 2121 disposed in the bendable area B and a second sub-part 2122 disposed in the second area S2, and the third part 131 disposed in the bendable area B may be disposed in the same layer as the first sub-part 2121, so that it can be ensured that the bendable arca B is provided with one conductive layer. The third structure 21 includes a first part 211 disposed in the first area S1. The first part 211 includes a first main portion 2111 extending in the first direction X to realize the connection of the third structure 21 with the fourth structure 22 and the fifth structure 23. The first part 211 may include at least a first conductive layer N1. The first conductive layer N1 is disposed in the same layer as the first signal transmission layer M1 or the second signal transmission layer M2. The fourth part 132 extends in the second direction Y to the active area A and is connected to the fifth part 133, so as to transmit the first power signal to the active area A. When the fourth part 132 includes at least one conductive layer, the at least one conductive layer is disposed in a different layer from the first main portion 2111 of the third structure 21, avoiding a cross short circuit between the fourth part 132 and the first main portion 2111. The first branch portion 2112 of the third structure 21 extends to the active area A for providing the second power signal to the active area A. The fifth part 133 may be disposed in a different layer from the first branch portion 2112, reducing the risk of a cross short circuit between the fifth part 133 and the first branch portion 2112 in the same layer. By way of example, when the first branch portion 2112 is disposed in the same layer as the first signal transmission layer M1 or the second signal transmission layer M2, the fifth part 133 may be disposed in the same layer as the second signal transmission layer M2 or the first signal transmission layer M1. When the first branch portion 2112 is disposed in the same layer as the third signal transmission layer M3 or the anode layer M4, the fifth part 133 may be disposed in the same layer as at least one of the second signal transmission layer M2 and the first signal transmission layer M1.

Still referring to FIGS. 17 and 18, the fourth part 132 includes a third sub-part 1321, a fourth sub-part 1322 and a fifth sub-part 1323. The third sub-part 1321 is disposed between the third structure 21 and the fourth structure 22, the fourth sub-part 1322 is disposed between the third structure 21 and the fifth structure 23, and the fifth sub-part 1323 is disposed on a side of the third sub-part 1321 and the fourth sub-part 1322 close to the active area A. The fifth sub-part 1323 extends in the first direction X and is connected to the third sub-part 1321 and the fourth sub-part 1322.

Specifically, the third sub-part 1321 may be connected to the first structure 11, the fourth sub-part 1322 may be connected to the second structure 12, and the fifth sub-part 1323 extends in the first direction X and is connected to third sub-part 1321 and the fourth sub-part 1322, so that first power signals transmitted by the first structure 11 and the second structure 12 are transmitted to the fifth sub-part 1323 through the third sub-part 1321 and the fourth sub-part 1322, respectively. The fifth sub-part 1323 is connected to the fifth part 133, so that the first power signal is transmitted through the fifth sub-part 1323 to the active area A.

In some embodiments, the fifth part 133 may include a plurality of branch portions, each of which may be connected to the fifth sub-part 1323 for providing a first power signal for at least one pixel within the active area A. The plurality of branch portions may be connected to different pixels, so that the lengths of signal lines along which the first power signal is transmitted to the pixels can be reduced, and the impedance voltage drop of the first power signal can thus be reduced, thereby facilitating an improvement in the brightness uniformity of the display panel. By way of example, the number of branch portions of the fifth part 133 is the same as the number of sub-pixels in one row, such that each branch portion may provide a first power signal for one column of sub-pixels, so that the impedance voltage drop of the first power signal can be reduced, thereby facilitating an improvement in brightness uniformity of the display panel.

In some embodiments, the third part 131 is disposed in the same layer as the third sub-part 1321 and the fourth sub-part 1322.

Specifically, the third part 131 may be disposed in the same layer as the first signal transmission layer M1 or the second signal transmission layer M2. The third part 131 is disposed in the same layer as the third sub-part 1321 and the fourth sub-part 1322, such that the number of film layers required for the first power signal transmission structure 10 can be reduced without the need for additional conductive layers, thereby facilitating the simplification of the wiring of the first power signal transmission structure 10 and the second power signal transmission structure 20.

In some embodiments, the active area A includes a first signal transmission layer M2 and a second signal transmission layer M3. The second signal transmission layer M3 is disposed on a side of the first signal transmission layer M2 close to the light exit surface, and the third sub-part 1321 and the fourth sub-part 1322 are disposed in the same layer as the first signal transmission layer M1 or the second signal transmission layer M2.

Specifically, when the third sub-part 1321 and the fourth sub-part 1322 are disposed in the same layer as the first signal transmission layer M1, the third part 131 is disposed in the same layer as the first signal transmission layer M1, in which case the first conductive layer N1 of the first part 211 may be disposed in the same layer as the second signal transmission layer M2, such that the first part 211 is disposed in a different layer from the third sub-part 1321 and the fourth sub-part 1322, reducing the risk of a cross short circuit between the third sub-part 1321 and the fourth sub-part 1322 when extending in the second direction Y and the first part 211 when extending in the first direction X, and improving the reliability of the array substrate. When the third sub-part 1321 and the fourth sub-part 1322 are disposed in the same layer as the second signal transmission layer M2, the third part 131 is disposed in the same layer as the second signal transmission layer M2, in which case the first conductive layer N1 of the first part 211 may be disposed in the same layer as the first signal transmission layer M1, such that the first part 211 is disposed in a different layer from the third sub-part 1321 and the fourth sub-part 1322, reducing the risk of a cross short circuit between the third sub-part 1321 and the fourth sub-part 1322 when extending in the second direction Y and the first part 211 when extending in the first direction X, and improving the reliability of the array substrate. By way of example, when the first signal transmission layer M1 is a third metal layer and the second signal transmission layer M2 is a fourth metal layer, the part of the first power signal transmission structure 10 located in the bendable area B and the third sub-part 1321 and the fourth sub-part 1322 located in the first area S1 are disposed in the same layer as the fourth metal layer.

In some embodiments, the fifth sub-part 1323 includes one eighth conductive layer N8, the eighth conductive layer N8 being disposed in the same layer as the first signal transmission layer M1 or the second signal transmission layer M2.

Specifically, when the first part 211 includes the first main portion 2111, the first main portion 2111 extends in the first direction X. The fifth sub-part 1323 also extends in the first direction X. When the first main portion 2111 and the fifth sub-part 1323 are disposed in the same layer, the first main portion 2111 may be disconnected from the fifth sub-part 1323 to avoid a cross short circuit. The fifth sub-part 1323 may include one eighth conductive layer N8. In this case, the fifth sub-part 1323 may be disposed in the same layer as the third sub-part 1321 and the fourth sub-part 1322, so that the structure and the fabrication process of the first power signal transmission structure 10 can be simplified. Moreover, the first main portion 2111 may be disposed in a different layer from the fifth sub-part 1323 to alleviate the cross short circuit phenomenon of the two. By way of example, when the fifth sub-part 1323 is disposed in the same layer as the first signal transmission layer M1, the first main portion 2111 may be disposed in the same layer as the second signal transmission layer M2. Furthermore, the fifth part 133 may be disposed in the same layer as the first signal transmission layer M1, further simplifying the structure and the fabrication process of the first power signal transmission structure 10. When the fifth sub-part 1323 is disposed in the same layer as the second signal transmission layer M2, the first main portion 2111 may be disposed in the same layer as the first signal transmission layer M1. Furthermore, the fifth part 133 may be disposed in the same layer as the second signal transmission layer M2, further simplifying the structure and the fabrication process of the first power signal transmission structure 10.

In some embodiments, with reference to FIG. 19, the fifth sub-part 1323 may alternatively include two eighth conductive layers N8 connected in parallel. One of the eighth conductive layers N8 is disposed in the same layer as the first signal transmission layer M1, and the other eighth conductive layer N8 is disposed in the same layer as the second signal transmission layer M2.

Specifically, by configuring the fifth sub-part 1323 to include two eighth conductive layer N8 connected in parallel, the equivalent impedances of at least the two eighth conductive layer N8 can be connected in parallel, so that the equivalent impedance of the fifth sub-part 1323 can be reduced, thereby facilitating an improvement in the consistency of first power signals received by different pixels in the active arca A, and thus facilitating an improvement in the brightness uniformity of the display panel. In one embodiment, the width of the fifth sub-part 1323 in the second direction Y can be reduced under the same equivalent impedance conditions to facilitate the implementation of a narrow-bezel design of the display panel. The two eighth conductive layers N8 of the fifth sub-part 1323 may be disposed in the same layers as the first signal transmission layer M1 and the second signal transmission layer M2, respectively, to avoid the need for additional film layers. In this case, the fifth sub-part 1323 is disconnected from the first main portion 2111 of the first part 211, thereby avoiding a cross short circuit between the fifth sub-part 1323 and the first main portion 2111. In addition, the first branch portion 2112 is disposed in a different layer from the fifth part 133, to avoid a cross short circuit between the two in the same layer. By way of example, when the first branch portion 2112 is disposed in the same layer as the first signal transmission layer M1 or the second signal transmission layer M2, the fifth part 133 may be disposed in the same layer as the second signal transmission layer M2 or the first signal transmission layer M1. When the first branch portion 2112 is disposed in the same layer as the third signal transmission layer M3 or the anode layer M4, the first branch portion 2112 may be the fifth part 133 may be disposed in the same layer as one of the second signal transmission layer M2 and the first signal transmission layer M1. By way of example, when the first signal transmission layer M1 is a third metal layer and the second signal transmission layer M2 is a fourth metal layer, the fifth sub-part 1323 of the first power signal transmission structure 10 located in the first area S1 is a parallel connection structure of the third metal layer and the fourth metal layer.

Still referring to FIG. 17, the third sub-part 1321 includes a third main portion 13211 and at least one third branch portion 13212. The third main portion 13211 extends in the first direction X and is connected to the third part 131; and the third branch portion 13212 is disposed on a side of the third main portion 13211 close to the active area A, and the third branch portion 13212 is connected to the fifth sub-part 1323.

Specifically, the third main portion 13211 extends in the first direction X and the third branch portion 13212 extends in the second direction Y, so that the width of the third sub-part 1321 can be increased, and the equivalent impedance of the third sub-part 1321 can then be reduced, thereby facilitating an improvement in the consistency of the first power signals obtained by different pixels in the active area A, and thus facilitating an improvement in the brightness uniformity of the display panel. By way of example, when the first signal transmission layer M1 is a third metal layer and the second signal transmission layer M2 is a fourth metal layer, the third main portion 13211 and the third branch portion 13212 may be a single-layer metal structure, for example, disposed in the same layer as the fourth metal layer.

Still referring to FIG. 18, the fourth sub-part 1322 includes a fourth main portion 13221 and at least one fourth branch portion 13222. The fourth main portion 13221 extends in the first direction X and is connected to the third part 131; and the fourth branch portion 13222 is disposed on a side of the fourth main portion 13221 close to the active arca A, and the fourth branch portion 13221 is connected to the fifth sub-part 1323.

Similarly, the fourth main portion 13221 extends in the first direction X and the fourth branch portion 13222 extends in the second direction Y, so that the width of the fourth sub-part 1322 can be increased, and the equivalent impedance of the fourth sub-part 1322 can then be reduced, thereby facilitating an improvement in the consistency of the first power signals obtained by different pixels in the active area A, and thus facilitating an improvement in the brightness uniformity of the display panel. By way of example, when the first signal transmission layer M1 is a third metal layer and the second signal transmission layer M2 is a fourth metal layer, the fourth main portion 13221 and the fourth branch portion 13222 may be a single-layer metal structure, for example, disposed in the same layer as the fourth metal layer.

It should be noted that in some embodiments, at least one of the third branch portion 13212 and the fourth branch portion 13222 may be a planar structure, so that the area of at least one of the third branch portion 13212 and the fourth branch portion 13222 can be increased, thereby facilitating a further reduction in the equivalent impedance of at least one of the third branch portion 13212 and the fourth branch portion 13222, and the equivalent impedance of at least one of the third sub-part 1321 and the fourth sub-part 1322 can be reduced, facilitating an improvement in the consistency of the first power signals obtained by different pixels in the active area A, and thus facilitating an improvement in the brightness uniformity of the display panel. By way of example, when the first conductive layer N1 of the first main portion 2111 is disposed in the same layer as the first signal transmission layer M1, and the second conductive layer M2 of the first main portion 2111 is disposed in the same layer as the third signal transmission layer M3 or the anode layer M4. At least one of the third branch portion 13212 and the fourth branch portion 13222 is provided with a via hole, and the bridging portion K1 is disposed in the via hole, so that the first conductive layer N1 and the second conductive layer N2 are connected to each other via the bridging portion K1.

In some embodiments, as shown in FIG. 17, the third sub-part 1321 includes a plurality of third branch portions 13212, the plurality of third branch portions 13212 being arranged at intervals.

Specifically, as shown in FIG. 17, the third branch portion 13212 may also be of a linear structure, and different third branch portions 13212 are arranged at intervals, such that when a foreign object exists at the interval between adjacent third branch portions 13212, the risk of a short circuit between the third branch portions 13212 caused by the foreign object can be avoided, thereby reducing the risk probability of the short circuit between the third branch portions 13212 caused by the foreign object, and improving the reliability of the third branch portions 13212.

In some embodiments, the fourth sub-part 1322 includes a plurality of fourth branch portions 13222, the plurality of fourth branch portions 13222 being arranged at intervals.

Similarly, further referring to FIG. 18, the fourth branch portion 13222 may also be of a linear structure, and different fourth branch portions 13222 are arranged at intervals, such that when a foreign object exists at the interval between adjacent fourth branch portions 13222, the risk of a short circuit between the fourth branch portions 13222 caused by the foreign object can be avoided, thereby reducing the risk probability of the short circuit between the fourth branch portions 13222 caused by the foreign object, and improving the reliability of the fourth branch portions 13222.

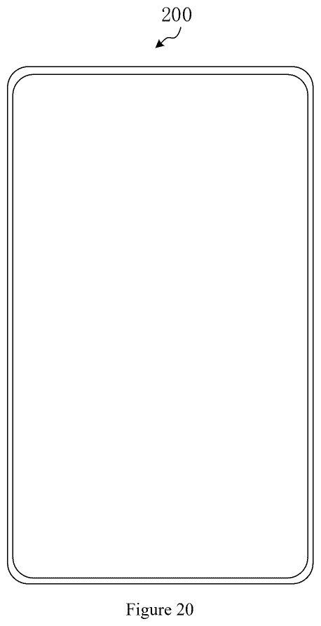

The embodiments of the present disclosure further provide a display panel. FIG. 20 is a structural schematic view of a display panel according to an embodiment of the present disclosure. As shown in FIG. 20, the display panel 200 includes the array substrate provided in any embodiment of the present disclosure. As the display panel includes the array substrate provided in any embodiment of the present disclosure, the display panel has the same beneficial effects as the array substrate provided in any embodiment of the present disclosure, which will not be described again herein. The display panel may be, for example, a cell phone, a tablet computer, a television, a display, a laptop computer, a digital photo frame, a smart wearable device, an information kiosk in a public hall, or any product or component with a display function.

It is to be noted that only preferred embodiments of the present disclosure and the principles employed have been described above. The present disclosure is not limited to the particular embodiments described herein and that various obvious changes, readjustments, and substitutions can be made without departing from the scope of protection of the present disclosure. Therefore, although the present disclosure has been described in detail through the above embodiments, the present disclosure is not limited to the above embodiments, and can also include more other equivalent embodiments without departing from the concept of the present disclosure, and the scope of the present disclosure is determined by the scope of the appended claims.

1. An array substrate, comprising an active area, a first area, a bendable area, and a second area that are arranged in a second direction, and further comprising a first power signal transmission structure and a second power signal transmission structure,
wherein in the second area, the first power signal transmission structure comprises a first structure and a second structure that are insulated from each other, the first structure and the second structure being arranged in a first direction; and
the second power signal transmission structure comprises a third structure, a part of the third structure located in the second area being disposed between the first structure and the second structure, and the third structure extending in the second direction to the active area, wherein the second direction intersects the first direction.

2. The array substrate according to claim 1, wherein the second power signal transmission structure further comprises a fourth structure and a fifth structure, the fourth structure being disposed on a side of the first structure away from the third structure, and the fifth structure being disposed on a side of the second structure away from the third structure,
wherein the third structure, the fourth structure and the fifth structure are connected in the first area.

3. The array substrate according to claim 2, wherein the third structure comprises a first part and a second part, the first part of the third structure being disposed in the first area, and the second part of the third structure being disposed in the bendable area and the second area; the first part comprises a first main portion and at least one first branch portion, the first main portion extending in the first direction and being connected to the fourth structure and the fifth structure, and the first branch portion extending in the second direction to the active area;
the array substrate further comprises a third area, the third area and the active area being arranged in the first direction; the first area comprises a rounded corner area and a bezel area, the rounded corner area being disposed between the third area and the bezel area; in the bezel area, at least one of: the fourth structure and the fifth structure comprises a second main portion and at least one second branch portion; the second main portion extends in the first direction and is connected to the first main portion; the second branch portion extends in the second direction to the active area;
the number of first branch portions and the number of second branch portions are equal to the number of sub-pixels in one row within the active area;
the third structure, the fourth structure, and the fifth structure are connected in parallel;
the active area comprises a signal transmission layer configured to provide a drive signal to at least one pixel of the active area; and at least part of the first part of the third structure is disposed in the same layer as the signal transmission layer.

4. The array substrate according to claim 3, wherein the signal transmission layer comprises a first signal transmission layer and a second signal transmission layer, the second signal transmission layer being disposed on a side of the first signal transmission layer close to a light exit surface; the first main portion of the third structure comprises a first conductive layer, the first conductive layer being disposed in the same layer as the first signal transmission layer or the second signal transmission layer;
the first branch portion of the third structure is disposed in the same layer as the first main portion; and
the first conductive layer of the first main portion comprises a first lower layer, a first middle layer and a first upper layer that are disposed in a stack, the first lower layer, the first middle layer and the first upper layer being conductive layers.

5. The array substrate according to claim 4, wherein the signal transmission layer further comprises a third signal transmission layer disposed on a side of the second signal transmission layer close to the light exit surface; the first main portion further comprises a second conductive layer, the first conductive layer being connected to the second conductive layer, and the second conductive layer being disposed in the same layer as the third signal transmission layer;
the first conductive layer and the second conductive layer are connected in parallel;
the first branch portion is disposed in the same layer as the third signal transmission layer; and
the second conductive layer comprises a second lower layer, a second middle layer, and a second upper layer that are disposed in a stack, the second lower layer, the second middle layer and the second upper layer being conductive layers.

6. The array substrate according to claim 4, wherein the active area comprises an anode layer disposed on a side of the second signal transmission layer close to the light exit surface and configured to form at least one anode of the at least one pixel in the active area; the first main portion further comprises a second conductive layer, the first conductive layer being connected to the second conductive layer, and the second conductive layer being disposed in the same layer as the anode layer;
the first conductive layer and the second conductive layer are connected in parallel; and
the first branch portion is disposed in the same layer as the anode layer.

7. The array substrate according to claim 6, further comprising a third area, the third area and the active area being arranged in the first direction, wherein the first area comprises a rounded corner area and a bezel area, the rounded corner area being disposed between the third area and the bezel area; in the bezel area, at least one of: the fourth structure and the fifth structure comprises a third conductive layer and a fourth conductive layer that are connected in parallel, the third conductive layer being disposed in the same layer as the first signal transmission layer, and the fourth conductive layer being disposed in the same layer as the second signal transmission layer; and
at least one of: the fourth structure and the fifth structure further comprises a fifth conductive layer connected in parallel with the third conductive layer and the fourth conductive layer, the fifth conductive layer being disposed in the same layer as a third signal transmission layer or an anode layer.

8. The array substrate according to claim 6, wherein when the first conductive layer of the third structure is disposed in the same layer as the first signal transmission layer, the second signal transmission layer further comprises a bridging portion via which the first conductive layer of the third structure and the second conductive layer of the third structure are connected to each other.

9. The array substrate according to claim 3, wherein the second part of the third structure comprises a first sub-part and a second sub-part, wherein the first sub-part of the third structure is disposed in the bendable area, and the second sub-part of the third structure is disposed in the second area; the first sub-part is disposed in the same layer as part of the signal transmission layer, and the second sub-part is disposed in the same layer as the signal transmission layer;
the signal transmission layer comprises a first signal transmission layer and a second signal transmission layer, the first sub-part being disposed in the same layer as the first signal transmission layer or the second signal transmission layer; and
the second sub-part comprises a sixth conductive layer and a seventh conductive layer that are connected in parallel, the sixth conductive layer being disposed in the same layer as the first signal transmission layer, and the seventh conductive layer being disposed in the same layer as the second signal transmission layer.

10. The array substrate according to claim 9, wherein the first sub-part of the second part of the third structure is disposed in a different layer from the first part of the third structure.

11. The array substrate according to claim 2, wherein at least one conductive layer of the fourth structure is disposed in the same layer as the first part; and
at least one conductive layer of the fifth structure is disposed in the same layer as the first part.

12. The array substrate according to claim 2, wherein in the first direction, the first structure and the second structure are symmetrically disposed about the third structure; and
in the first direction, the fourth structure and the fifth structure are symmetrically disposed about the third structure.

13. The array substrate according to claim 1, wherein the first power signal transmission structure further comprises a sixth structure, wherein the sixth structure is disposed in the first area and the bendable area and extends to the active area; and the sixth structure is connected to the first structure and the second structure.

14. The array substrate according to claim 13, wherein the sixth structure of the first power signal transmission structure comprises a third part, a fourth part, and a fifth part, wherein the third part is disposed in the bendable area, the fourth part is disposed in the first area, and the fifth part is disposed in the active area; the third part is disposed in the same layer as at least part of the fourth part, and the fourth part is disposed in the same layer as at least part of the fifth part;
the third part is disposed in the same layer as at least part of a second part of the third structure; and the fourth part and the fifth part are disposed in a different layer from at least part of a first part of the third structure.

15. The array substrate according to claim 14, wherein the fourth part of the sixth structure of the first power signal transmission structure comprises a third sub-part, a fourth sub-part, and a fifth sub-part,
wherein the third sub-part is disposed between the third structure of the second power signal transmission structure and the fourth structure of the second power signal transmission structure, the fourth sub-part is disposed between the third structure and the fifth structure of the second power signal transmission structure, the fifth sub-part is disposed on a side of the third sub-part and the fourth sub-part close to the active area, and the fifth sub-part extends in the first direction and is connected to the third sub-part and the fourth sub-part.

16. The array substrate according to claim 15, wherein the third part of the sixth structure of the first power signal transmission structure is disposed in the same layer as the third sub-part and the fourth sub-part of the fourth part of the sixth structure;
the active area comprises a first signal transmission layer and a second signal transmission layer, the second signal transmission layer being disposed on a side of the first signal transmission layer close to a light exit surface, and the third sub-part and the fourth sub-part being disposed in the same layer as the first signal transmission layer or the second signal transmission layer; and
the fifth sub-part comprises one eighth conductive layer disposed in the same layer as the first signal transmission layer or the second signal transmission layer;
the fifth sub-part comprises two eighth conductive layers connected in parallel, one of the eighth conductive layers being disposed in the same layer as the first signal transmission layer, and the other of the eighth conductive layers being disposed in the same layer as the second signal transmission layer.

17. The array substrate according to claim 16, wherein the fifth part of the sixth structure of the first power signal transmission structure is disposed in the same layer as the first signal transmission layer or the second signal transmission layer.

18. The array substrate according to claim 15, wherein the third sub-part of the fourth part of the sixth structure of the first power signal transmission structure comprises a third main portion and at least one third branch portion, wherein the third main portion extends in the first direction and is connected to the third part, and the third branch portion is disposed on a side of the third main portion close to the active area and connected to the fifth sub-part; and
the fourth sub-part of the fourth part of the sixth structure of the first power signal transmission structure comprises a fourth main portion and at least one fourth branch portion, wherein the fourth main portion extends in the first direction and is connected to the third part, and the fourth branch portion is disposed on a side of the fourth main portion close to the active area and connected to the fifth sub-part.

19. The array substrate according to claim 17, wherein the third sub-part of the fourth part of the sixth structure of the first power signal transmission structure comprises a plurality of third branch portions, the plurality of third branch portions being disposed at intervals.

20. The array substrate according to claim 19, wherein the fourth sub-part of the fourth part of the sixth structure of the first power signal transmission structure comprises a plurality of fourth branch portions, the plurality of the fourth branch portions being disposed at intervals.
